(19) United States
(12) Patent Application Publication
(10) Pub. No.: US 2025/0331259 A1
(43) Pub. Date: Oct. 23, 2025

(54) LAMINATED STRUCTURE, THIN FILM TRANSISTOR, AND ELECTRONIC DEVICE

(71) Applicants: Japan Display Inc., Tokyo (JP); IDEMITSU KOSAN CO., LTD., Tokyo (JP)

(72) Inventors: Hajime WATAKABE, Tokyo (JP); Masashi TSUBUKU, Tokyo (JP); Toshinari SASAKI, Tokyo (JP); Takaya TAMARU, Tokyo (JP); Marina MOCHIZUKI, Tokyo (JP); Ryo ONODERA, Tokyo (JP); Masahiro WATABE, Tokyo (JP); Daichi SASAKI, Tokyo (JP); Emi KAWASHIMA, Tokyo (JP); Yuki TSURUMA, Tokyo (JP)

(73) Assignees: Japan Display Inc., Tokyo (JP); IDEMITSU KOSAN CO., LTD., Tokyo (JP)

(21) Appl. No.: 19/259,174

(22) Filed: Jul. 3, 2025

Related U.S. Application Data
(63) Continuation of application No. PCT/JP2023/046215, filed on Dec. 22, 2023.

(30) Foreign Application Priority Data
Jan. 19, 2023 (JP) 2023-006863

(51) Int. Cl. H10D 62/40; H10D 30/67

(52) U.S. Cl. CPC H10D 62/405; H10D 30/6755

(57) ABSTRACT

A laminated structure includes a metal oxide layer and an oxide semiconductor layer having crystallinity over and in contact with the metal oxide layer. A crystal structure of the oxide semiconductor layer is a bixbyite structure. At least a first peak of a (222) plane and a second peak of a (440) plane are observed in a diffraction pattern of the oxide semiconductor layer obtained by an out-of-plane XRD measurement using Cu—Kα radiation. A ratio of an intensity of the first peak to an intensity of the second peak is greater than or equal to 6 and less than or equal to 15.

### CROSS-REFERENCE TO RELATED APPLICATIONS

This application is a Continuation of International Patent Application No. PCT/JP2023/046215, filed on Dec. 22, 2023, which claims the benefit of priority to Japanese Patent Application No. 2023-006863, filed on Jan. 19, 2023, the entire contents of each are incorporated herein by reference.

### FIELD

An embodiment of the present invention relates to a laminated structure including an oxide semiconductor film having a polycrystalline structure (Poly-OS). Further, an embodiment of the present invention relates to a thin film transistor including the laminated structure. Furthermore, an embodiment of the present invention relates to an electronic device including the thin film transistor.

### BACKGROUND

In recent years, instead of a silicon semiconductor film using amorphous silicon, low-temperature polysilicon, and single-crystal silicon, a thin film transistor in which an oxide semiconductor film is used for a channel has been developed (for example, see Japanese laid-open patent publication Nos. 2021-141338, 2014-099601, 2021-153196, 2018-006730, 2016-184771, and 2021-108405). The thin film transistor including an oxide semiconductor film can be manufactured with a simple structure and low-temperature process, similar to a thin film transistor including an amorphous silicon film. Further, the thin film transistor including an oxide semiconductor film is known to have a higher field-effect mobility than the thin film transistor including an amorphous silicon film.

### SUMMARY

A laminated structure according to an embodiment of the present invention includes a metal oxide layer and an oxide semiconductor layer having crystallinity over and in contact with the metal oxide layer. A crystal structure of the oxide semiconductor layer is a bixbyite structure. At least a first peak of a (222) plane and a second peak of a (440) plane are observed in a diffraction pattern of the oxide semiconductor layer obtained by an out-of-plane XRD measurement using Cu—Kα radiation. A ratio of an intensity of the first peak to an intensity of the second peak is greater than or equal to 6 and less than or equal to 15.

A thin film transistor according to an embodiment of the present invention includes the laminated structure, a gate electrode provided so as to face the oxide semiconductor layer, and a gate insulating layer provided between the oxide semiconductor film and the gate electrode.

An electronic device according to an embodiment of the present invention includes the thin film transistor.

### BRIEF DESCRIPTION OF DRAWINGS

FIG. 1A is an example of a diffraction pattern of an oxide semiconductor film according to an embodiment of the present invention, obtained by an out-of-plane XRD measurement.

FIG. 1B is an example of a diffraction pattern of an oxide semiconductor film according to an embodiment of the present invention, obtained by an out-of-plane XRD measurement.

FIG. 2 is a schematic cross-sectional view showing a configuration of a thin film transistor according to an embodiment of the present invention.

FIG. 3 is a schematic plan view showing a configuration of a thin film transistor according to an embodiment of the present invention.

FIG. 4 is a flowchart showing a method for manufacturing a thin film transistor according to an embodiment of the present invention.

FIG. 5 is a schematic cross-sectional view showing a method for manufacturing a thin film transistor according to an embodiment of the present invention.

FIG. 6 is a schematic cross-sectional view showing a method for manufacturing a thin film transistor according to an embodiment of the present invention.

FIG. 7 is a schematic cross-sectional view showing a method for manufacturing a thin film transistor according to an embodiment of the present invention.

FIG. 8 is a schematic cross-sectional view showing a method for manufacturing a thin film transistor according to an embodiment of the present invention.

FIG. 9 is a schematic cross-sectional view showing a method for manufacturing a thin film transistor according to an embodiment of the present invention.

FIG. 10 is a schematic cross-sectional view showing a method for manufacturing a thin film transistor according to an embodiment of the present invention.

FIG. 11 is a schematic cross-sectional view showing a method for manufacturing a thin film transistor according to an embodiment of the present invention.

FIG. 12 is a schematic cross-sectional view showing a method for manufacturing a thin film transistor according to an embodiment of the present invention.

FIG. 13 is a schematic diagram showing an electronic device according to an embodiment of the present invention.

FIG. 14 is a graph plotting a field effect mobility of a thin film transistor versus a (222)/(440) peak intensity ratio of an oxide semiconductor film.

FIG. 15 is a graph plotting a field effect mobility of a thin film transistor versus a (222)/(440) peak intensity ratio of an oxide semiconductor film.

### DESCRIPTION OF EMBODIMENTS

The field effect mobility of a thin film transistor including a conventional oxide semiconductor film is not so high even when a crystalline oxide semiconductor film is used in the thin film transistor. Therefore, it has been desired to improve the crystal structure of the oxide semiconductor film used in the thin film transistor and thereby improve the field effect mobility of the thin film transistor.

In view of the above problems, an embodiment of the present invention can provide a laminated structure including an oxide semiconductor film having a novel crystal structure. Further, an embodiment of the present invention can provide a thin film transistor including the laminated structure. Furthermore, an embodiment of the present invention can provide an electronic device including the thin film transistor.

Hereinafter, embodiments of the present invention are described with reference to the drawings. The following invention is merely an example. A configuration that can easily be conceived by a person skilled in the art by appropriately changing the configuration of the embodiment while keeping the gist of the invention is naturally included in the scope of the present invention. In order to make the description clearer, the drawings may schematically show the widths, thicknesses, shapes, and the like of components in comparison with the actual embodiments. However, the illustrated shapes are merely examples, and do not limit the interpretation of the present invention. In the present specification and the drawings, the same reference signs are given to components similar to those described previously with respect to the above-described drawings, and detailed description thereof may be omitted as appropriate.

In the present specification and the like, a direction from a substrate toward an oxide semiconductor layer is referred to as “on” or “over” in each embodiment of the present invention. Conversely, a direction from the oxide semiconductor layer to the substrate is referred to as “under” or “below.” For convenience of explanation, the phrase “over” or “below” is used for description, but for example, the substrate and the oxide semiconductor layer may be arranged so that the vertical relationship is reversed from that shown in the drawings. Further, the expression “an oxide semiconductor layer on a substrate” merely describes the vertical relationship between the substrate and the oxide semiconductor layer as described above, and another member may be arranged between the substrate and the oxide semiconductor layer. The terms “over” or “below” mean a stacking order in which a plurality of layers is stacked, and may have a positional relationship in which a thin film transistor and a pixel electrode do not overlap in a plan view when expressed as “a pixel electrode over a thin film transistor.” On the other hand, the expression “a pixel electrode vertically over a thin film transistor” means a positional relationship in which the thin film transistor and the pixel electrode overlap in a plan view. In addition, a plan view refers to viewing from a direction perpendicular to a surface of the substrate. In the present specification and the like, the terms “film” and “layer” can be optionally interchanged with one another.

In the present specification and the like, a “display device” refers to a structure that displays an image using an electro-optic layer. For example, the term “display device” may refer to a display panel that includes the electro-optic layer, or may refer to a structure with other optical members (for example, a polarized member, a backlight, a touch panel, and the like) attached to a display cell. The “electro-optic layer” may include a liquid crystal layer, an electroluminescent (EL) layer, an electrochromic (EC) layer, or an electrophoretic layer, as long as there is no technical contradiction. Therefore, although a liquid crystal display device including a liquid crystal layer and an organic EL display device including an organic EL layer are exemplified as a display device in the following embodiments, the structure according to the present embodiment can be applied to a display device including the other electro-optic layers described above.

In the present specification and the like, the expression “a includes A, B, or C,” “a includes any of A, B, or C,” or “a includes one selected from a group consisting of A, B and C,” and the like does not exclude the case where a includes a plurality of combinations of A to C unless otherwise specified. Further, these expressions do not exclude the case where a includes other components.

In addition, the following embodiments can be combined with each other as long as there is no technical contradiction.

### First Embodiment

An oxide semiconductor film according to an embodiment of the present invention is described.

### [1. Composition of Oxide Semiconductor Film]

The oxide semiconductor film according to the present embodiment contains indium (In) and at least one or more metal elements (M) other than indium. That is, the metal elements other than indium contained in the oxide semiconductor film may be one type of metal element or may be a plurality of types of metal elements. It is preferable that the composition ratio of the oxide semiconductor film has an atomic ratio of indium and at least one or more metal elements which satisfies Formula (1). In other words, it is preferable that the ratio of indium to all metal elements in the oxide semiconductor film is greater than or equal to 50%. When the ratio of indium in the oxide semiconductor film increases, the oxide semiconductor film having crystallinity can be formed. Further, it is preferable that a crystal structure of the oxide semiconductor film has a bixbyite structure. When the ratio of indium in the oxide semiconductor film increases, the oxide semiconductor film having a bixbyite structure can be formed.

$$0.01 < \frac{[ M ]}{[ ln ] + [ M ]} < 0.5 \qquad ( 1 )$$

Although the details of a method for manufacturing the oxide semiconductor film are described later together with a method for manufacturing a thin film transistor, the oxide semiconductor film can be formed by a sputtering method. The composition of the oxide semiconductor film formed by the sputtering method depends on the composition of the sputtering target. When the sputtering target has the above-described composition, the oxide semiconductor film without composition deviation of the metal elements can be formed by the sputtering method. Therefore, the composition of the metal elements (indium and other metal elements) in the oxide semiconductor film may be equivalent to the composition of the metal elements in the sputtering target. For example, the composition of the metal elements in the oxide semiconductor film can be specified based on the composition of the metal elements in the sputtering target. In addition, oxygen contained in the oxide semiconductor film is not limited thereto because it changes depending on the process conditions of the sputtering method.

Further, the composition of the metal elements in the oxide semiconductor film can be specified by X-ray fluorescence analysis, electron probe micro analyzer (EPMA) analysis, or the like. Since the oxide semiconductor film has a polycrystalline structure, the composition of the oxide semiconductor film may be specified by X-ray diffraction (XRD). Specifically, the composition of the metal elements in the oxide semiconductor film can be specified based on the crystal structure and lattice constant of the oxide semiconductor film obtained by XRD.

### [2. Crystal Structure of Oxide Semiconductor Film]

The oxide semiconductor film according to the present embodiment has a polycrystalline structure including a plurality of crystal grains. Although the details of the method for manufacturing the oxide semiconductor film are described later, the oxide semiconductor film having a novel polycrystalline structure different from a conventional oxide semiconductor film can be formed using a polycrystalline oxide semiconductor (Poly-OS) technique. Therefore, hereinafter, the oxide semiconductor film having a polycrystalline structure according to the present embodiment may be referred to as a Poly-OS film in order to distinguish it from the conventional oxide semiconductor film having a polycrystalline structure.

Although the crystal structure of the Poly-OS film is not limited to a certain structure, it is preferable that the Poly-OS film has a bixbyite structure. The crystal structure of the Poly-OS film can be specified by an XRD method or an electron beam diffraction method.

The crystal structure of the Poly-OS film is different from that of the conventional oxide semiconductor film having a polycrystalline structure. Specifically, the present inventors have found that although the Poly-OS film has a polycrystalline structure, the polycrystalline structure of the Poly-OS film is different from that of a conventional oxide semiconductor film. That is, the present inventors have completed an oxide semiconductor film having a novel polycrystalline structure (Poly-OS film) different from that of the conventional oxide semiconductor film as a result of various trials and errors. The characteristics in the crystallinity of the Poly-OS film can be obtained by an XRD method.

There are two types of XRD measurement, an out-of-plane measurement and an in-plane measurement. The out-of-plane measurement can evaluate a lattice plane parallel to a surface of a film, and the in-plane measurement can evaluate a lattice plane perpendicular to a surface of a film. The characteristics of the Poly-OS film can be obtained in the out-of-plane measurement.

Here, in terms of the crystal plane of the bixbyite structure in the present specification, a (001) plane includes a (001) plane and its equivalent (100) and (010) planes. Similarly, a (101) plane includes a (101) plane and its equivalent (110) and (011) planes. Further, a (111) plane represents a (111) plane. Furthermore, in each plane, “1” may be “−1” and is considered to be an equivalent plane to each plane.

In addition, crystal planes include a (hk0) plane (h≠k, h and k are natural numbers), a (hhl) plane (h≠l, h and l are natural numbers), and a (hkl) plane (h≠k≠l, h, k, and l are natural numbers) other than a (001) plane, a (101) plane, and a (111) plane.

### [2-1. Peak Intensity in Diffraction Pattern]

When an oxide semiconductor film has crystallinity, a peak appears at a certain diffraction angle (2θ) in a diffraction pattern obtained by an out-of-plane measurement. For example, a conventional crystalline oxide semiconductor film containing indium whose ratio is greater than or equal to 50% and having a bixbyite structure has peaks at diffraction angles near 31 degrees and near 44 degrees in a diffraction pattern. The peak at the diffraction angle near 31 degrees is attributed to a (222) plane of the bixbyite structure. The peak at the diffraction angle near 44 degrees is attributed to a (422) plane of the bixbyite structure. Further, the peak intensity at the diffraction angle near 31 degrees is significantly greater than the peak intensity at the diffraction angle near 44 degrees. This means that many crystals having the (222) plane exist in a direction parallel to the surface of the oxide semiconductor film.

In addition, the diffraction angle of the diffraction pattern of the oxide semiconductor film may change depending on the composition of metal elements contained in the oxide semiconductor film or the manufacturing conditions of the oxide semiconductor film. Therefore, in the present specification, “near” an angle of a diffraction angle peak is defined to include a range of ±2 degrees.

A diffraction pattern of the Poly-OS film having a bixbyite structure also has a peak at the diffraction angle near 31 degrees, which corresponds to the (222) plane of the bixbyite structure. However, the peak intensity of the diffraction angle near 31 degrees of the Poly-OS film is smaller than the peak intensity of the diffraction angle near 31 degrees of a conventional crystalline oxide semiconductor film with the same film thickness. For example, the peak intensity of the diffraction angle near 31 degrees of the Poly-OS film is less than half the peak intensity of the diffraction angle near 31 degrees of the conventional crystalline oxide semiconductor film with the same film thickness.

In the diffraction pattern of the Poly-OS film, a peak may appear at the diffraction angle near 44 degrees. When a peak appears at the diffraction angle near 44 degrees, a ratio of the peak intensity at the diffraction angle near 31 degrees to the peak intensity at the diffraction angle near 44 degrees is less than or equal to 3.0. However, in the diffraction pattern of the Poly-OS film, a peak may not appear at the diffraction angle near 44 degrees. On the other hand, in the diffraction pattern of the Poly-OS film, a peak may appear at a diffraction angle near 52 degrees corresponding to a (440) plane of the bixbyite structure. These phenomena indicate that the Poly-OS film has few crystals having the (222) plane in the direction parallel to the surface of the Poly-OS film, and the orientation is relaxed. As a result, a state appears in which many crystals have the (440) plane in the direction parallel to the surface of the Poly-OS film, and the Poly-OS film has a unique crystal orientation different from the conventional crystalline oxide semiconductor film.

It is necessary to reduce noise in order to observe not only the peak of the (222) plane but also the peak of the (440) plane in the diffraction pattern of the Poly-OS film. In order to reduce noise in the XRD measurement, the scanning speed of the goniometer is set to less than or equal to 1.0 deg/min, preferably less than or equal to 0.5 deg/min to increase the intensity per diffraction angle. Although the measurement width is greater than or equal to 0.05 degrees for example, the measurement width is not limited thereto. When measured in this manner, a diffraction pattern with an S/N ratio greater than or equal to 15, preferably greater than or equal to 30, is obtained, and the reliability of the data is very high. In addition, the above-mentioned ranges of the scanning speed and measurement width are examples of conditions for improving the S/N ratio, and the ranges are not limited thereto. Here, the S/N ratio is defined as the ratio of the maximum intensity(S) of the peak of the (222) plane to the noise width (N). The maximum intensity(S) of the peak of the (222) plane is obtained from the diffraction pattern of the Poly-OS film after background subtraction. The noise width (N) is calculated by defining a baseline by linear approximation using the least squares method for intensity data at diffraction angles greater than or equal to 29 degrees and less than or equal to 30 degrees in the diffraction pattern of the Poly-OS film before background subtraction, and doubling the standard deviation (i.e., 2σ) of the difference from the baseline.

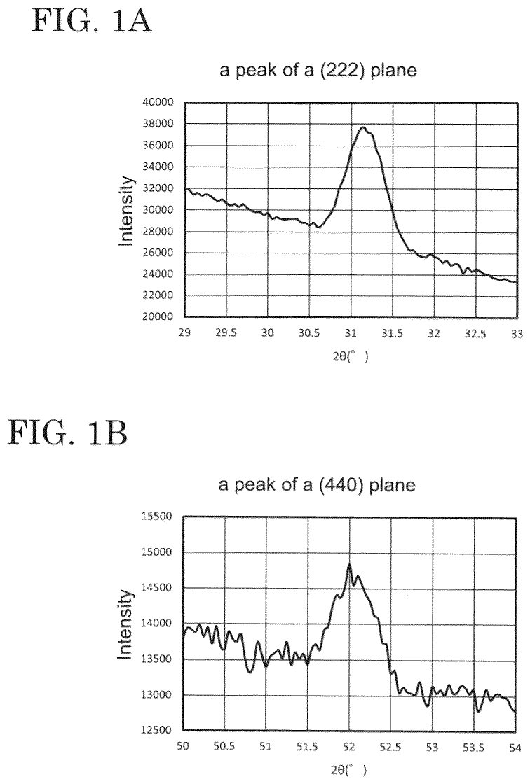

FIGS. 1A and 1B are examples of a diffraction pattern of an oxide semiconductor film (Poly-OS film) according to an embodiment of the present invention, obtained by an out-of-plane XRD measurement. The measurement conditions are a goniometer scanning speed of 0.5 deg/min and a measurement width of 0.05 degrees. As shown in FIGS. 1A and 1B, peaks of the (222) plane and the (440) plane can be observed near 31 degrees and near 52 degrees, respectively. The calculated S/N ratio is 27.0, and the intensity of the peak of the (440) plane has sufficiently high reliability.

As described above, the Poly-OS film shows a characteristic diffraction pattern different from that of the conventional crystalline oxide semiconductor film. Specifically, when the Poly-OS film has a bixbyite structure, a peak intensity of the (222) plane in the diffraction pattern is small. Further, a peak of the (440) plane appears in the Poly-OS film, which means that the orientation of the (222) plane with respect to the surface of the Poly-OS film is relaxed and the (440) plane is oriented in a direction parallel to the surface of the Poly-OS film. Thus, the crystals included in the Poly-OS film have a unique crystal orientation different from that of the conventional crystal.

One of the parameters indicating the characteristics of crystallinity of the Poly-OS film is the ratio of the peak intensity of the (222) plane to the peak intensity of the (440) plane (hereinafter, referred to as a “(222)/(440) peak intensity ratio”). In the conventional crystalline oxide semiconductor film, the peak intensity of the (222) plane is large, and a peak of the (440) plane is hardly observed. Therefore, the (222)/(440) peak intensity ratio of the conventional crystalline oxide semiconductor film cannot be calculated or exceeds 500. On the other hand, the (222)/(440) peak intensity ratio of the Poly-OS film is less than or equal to 300. Although the details are described later, when a thin film transistor using the Poly-OS film as a channel has a (222)/(440) peak intensity ratio less than or equal to 125, a field effect mobility greater than or equal to 30 cm²/Vs can be obtained. The (222)/(440) peak intensity ratio of the Poly-OS film is preferably greater than or equal to 6 and less than or equal to 15, more preferably greater than or equal to 9 and less than or equal to 12. When the (222)/(440) peak intensity ratio of the Poly-OS film is greater than or equal to 6 and less than or equal to 15, a field effect mobility greater than or equal to 38 cm²/Vs can be obtained. Further, when the (222)/(440) peak intensity ratio of the Poly-OS film is greater than or equal to 9 and less than or equal to 12, a field effect mobility greater than or equal to 40 cm²/Vs can be obtained in some cases.

### [2-2. Crystallite Size]

A crystal grain in the Poly-OS film may include a plurality of crystallites. A crystallite diameter D can be calculated by the Scherrer formula shown in Formula (2) using a peak width of the diffraction pattern. Here, K is the Scherrer constant, λ is the wavelength of the X-ray, β is the half-width of the peak, and θ is the Bragg angle (corresponding to ½ of the diffraction angle 2θ).

$$D = K λ / β cos θ \qquad ( 2 )$$

In the case of the Poly-OS film having a bixbyite structure, the crystallite diameter D of the crystal grains contained in the Poly-OS film can be calculated using the half-width of the peak corresponding to the (222) plane. In the out-of-plane diffraction pattern using Cu—K α rays, it is preferable that the crystallite diameter D is approximately equal to the film thickness t of the Poly-OS. For example, the ratio (D/t) of the crystallite diameter D to the film thickness t of the Poly-OS film is greater than or equal to 0.75, preferably greater than or equal to 0.85, and more preferably greater than or equal to 0.95. Although the film thickness t of the Poly-OS film is not particularly limited to a specific value, as the film thickness t becomes smaller, the D/t becomes larger, and a Poly-OS film having a small (222)/(440) peak intensity ratio can be obtained. For example, the film thickness t of the Poly-OS film is less than or equal to 30 nm, preferably less than or equal to 20, and more preferably less than or equal to 15 nm. In particular, when the film thickness is less than 20 nm, the Poly-OS film having a D/t greater than or 0.95 can be obtained. In addition, when the film thickness of the Poly-OS film is small, the crystallite diameter D may exceed the film thickness t of the Poly-OS film. In this case, D/t can be determined to be greater than or equal to 0.95 because the crystallite diameter D is approximately equal to the film thickness t of the Poly-OS film when the crystallite diameter D is a value close to the film thickness t of the Poly-OS film.

As described above, the peak intensity of the (222) plane in the diffraction pattern of the Poly-OS film is small. However, the crystallite diameter D of the Poly-OS film is almost equal to the film thickness t of the Poly-OS film. Therefore, the Poly-OS film has a novel crystal structure in which the crystal orientation is relaxed while the long-range atomic order is maintained in the film thickness direction (perpendicular to the film surface).

As described above, the oxide semiconductor film according to an embodiment of the present invention, that is, the Poly-OS film, has a novel crystal structure. Although the details are described later, when the Poly-OS film having such a novel crystal structure is used as a channel of a thin film transistor, the field effect mobility is not reduced but is actually improved. Therefore, the thin film transistor including the Poly-OS film has improved electrical characteristics.

### Second Embodiment

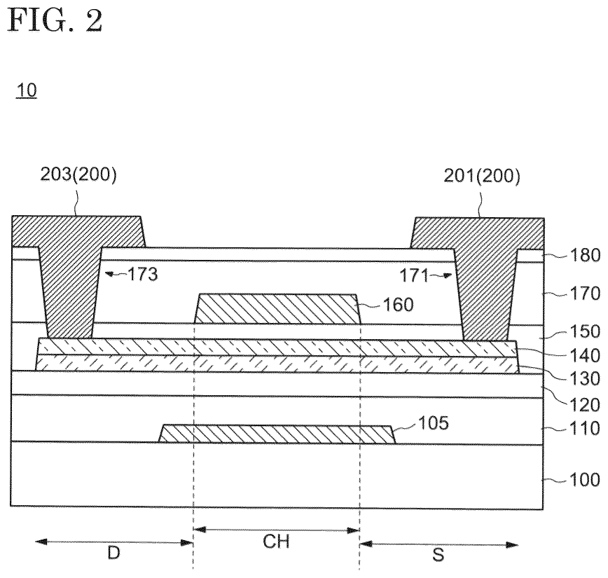

A thin film transistor 10 according to an embodiment of the present invention is described with reference to FIGS. 2 to 12. For example, the thin film transistor 10 may be used in an integrated circuit (IC) such as a micro-processing unit (MPU) or a memory circuit in addition to a transistor used in a display device.

### [1. Configuration of Thin Film Transistor 10]

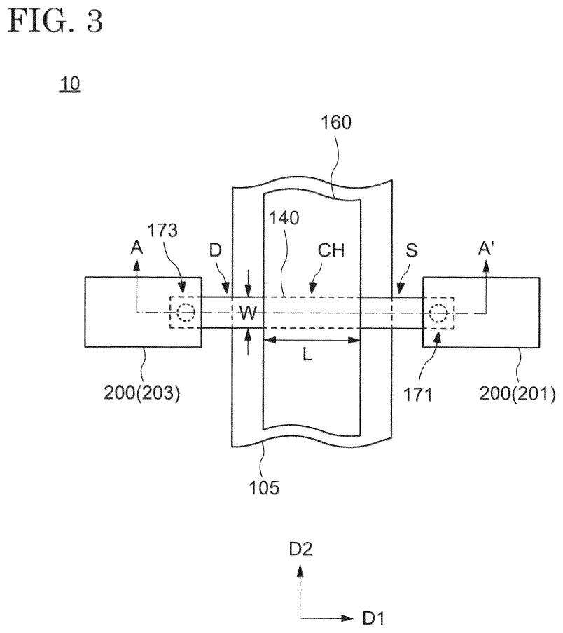

A configuration of a thin film transistor 10 according to an embodiment of the present invention is described with reference to FIGS. 2 and 3. FIG. 2 is a schematic cross-sectional view showing the configuration of the thin film transistor 10 according to an embodiment of the present invention. FIG. 3 is a schematic plan view showing the configuration of the thin film transistor 10 according to an embodiment of the present invention. Specifically, FIG. 2 is a cross-sectional view cut along the line A-A′ in FIG. 3.

As shown in FIG. 2, the thin film transistor 10 includes a substrate 100, a light shielding layer 105, a first insulating layer 110, a second insulating layer 120, a metal oxide layer 130, an oxide semiconductor layer 140, a gate insulating layer 150, a gate electrode 160, a third insulating layer 170, a fourth insulating layer 180, a source electrode 201, and a drain electrode 203. The light shielding layer 105 is provided on the substrate 100. The first insulating layer 110 is provided on the substrate 100 so as to cover an upper surface and an edge surface of the light shielding layer 105. The second insulating layer 120 is provided on the first insulating layer 110. The metal oxide layer 130 is provided on the second insulating layer 120. The oxide semiconductor layer 140 is provided to be in contact with the metal oxide layer 130. The gate insulating layer 150 is provided on the second insulating layer 120 so as to cover an edge surface of the metal oxide layer 140, and an upper surface and an edge surface of the oxide semiconductor layer 140. The gate electrode 160 is provided on the gate insulating layer 150 so as to overlap the oxide semiconductor layer 140. The third insulating layer 170 is provided on the gate insulating layer 150 so as to cover an upper surface and an edge surface of the gate electrode 160. The fourth insulating layer 180 is provided on the third insulating layer 170. The gate insulating layer 150, the third insulating layer 170, and the fourth insulating layer 180 are provided with opening portions 171 and 173 through which a part of the upper surface of the oxide semiconductor layer 140 is exposed. The source electrode 201 is provided on the fourth insulating layer 180 and inside the opening portion 171, and is in contact with the oxide semiconductor layer 140. Similarly, the drain electrode 203 is provided on the fourth insulating layer 180 and inside the opening portion 173, and is in contact with the oxide semiconductor layer 140. That is, the thin film transistor includes a laminated structure formed by the metal oxide layer 130 and the oxide semiconductor layer 140. In the following description, when the source electrode 201 and the drain electrode 203 are not particularly distinguished from each other, they may be collectively referred to as a source-drain electrode 200.

The oxide semiconductor layer 140 is divided into a source region S, a drain region D, and a channel region CH based on the gate electrode 160. That is, the oxide semiconductor layer 140 includes the channel region CH which overlaps the gate electrode 160 and the source region S and the drain region D which do not overlap the gate electrode 160. In a film thickness direction of the oxide semiconductor layer 140, an edge portion of the channel region CH is substantially aligned with an edge portion of the gate electrode 160. The channel region CH has properties of a semiconductor. Each of the source region S and the drain region D has properties of a conductor. Therefore, the electrical conductivities of the source region S and the drain region D are larger than the electrical conductivity of the channel region CH. The source electrode 201 and the drain electrode 203 are in contact with the source region S and the drain region D, respectively, and are electrically connected to the oxide semiconductor layer 140. Further, the oxide semiconductor layer 140 may have a single layer structure or a laminated structure.

As shown in FIG. 3, each of the light shielding layer 105 and the gate electrode 160 has a predetermined width in a direction D1 and extends in a direction D2 orthogonal to the direction D1. A width of the light shielding layer 105 is greater than a width of the gate electrode 160 in the direction D1. The channel region CH completely overlaps the light shielding layer 105. In the semiconductor device 10, the direction D1 corresponds to the direction in which a current flows from the source electrode 201 to the drain electrode 203 through the oxide semiconductor layer 140. Therefore, a length of the channel region CH in the direction D1 is a channel length L, and a width of the channel region CH in the direction D2 is a channel width W.

The substrate 100 can support each layer in the thin film transistor 10. For example, a rigid substrate with translucency such as a glass substrate, a quartz substrate, or a sapphire substrate can be used as the substrate 100. Further, a rigid substrate without translucency such as a silicon substrate can be used as the substrate 100. Furthermore, a flexible substrate with translucency such as a polyimide resin substrate, an acrylic resin substrate, a siloxane resin substrate, or a fluorine resin substrate can be used as the substrate 100. In order to improve the heat resistance of the substrate 100, impurities may be introduced into the resin substrate. In addition, a substrate in which a silicon oxide film or a silicon nitride film is formed over the rigid substrate or the flexible substrate described above can be used as the substrate 100.

The light shielding layer 105 can reflect or absorb external light. As described above, since the light shielding layer 105 has a larger area than the channel region CH of the oxide semiconductor layer 140, the light shielding layer 105 can block external light entering the channel region CH. For example, aluminum (Al), copper (Cu), titanium (Ti), molybdenum (Mo), tungsten (W), or alloys or compounds thereof can be used for the light shielding layer 105. Further, the light shielding layer 105 may not necessarily include a metal when conductivity of the light shielding layer 105 is not required. For example, a black matrix made of black resin can be used for the light shielding layer 105. Furthermore, the light shielding layer 105 may have a single layer structure or a laminated structure. For example, the light shielding layer 105 may have a laminated structure of a red color filter, a green color filter, and a blue color filter.

The first insulating layer 110, the second insulating layer 120, the third insulating layer 170, and the fourth insulating layer 180 can prevent impurities from diffusing into the oxide semiconductor layer 140. Specifically, the first insulating layer 110 and the second insulating layer 120 can prevent diffusion of impurities contained in the substrate 100, and the third insulating layer 170 and the fourth insulating layer 180 can prevent diffusion of impurities (for example, water) entering from the outside. For example, silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), or aluminum nitride (AlNₓ) and the like are used for each of the first insulating layer 110, the second insulating layer 120, the third insulating layer 170, and the fourth insulating layer 180. Here, silicon oxynitride (SiOₓN_{y}) and aluminum oxynitride (AlOₓN_{y}) are a silicon compound and an aluminum compound, respectively, that contain a smaller proportion (x>y) of nitrogen (N) than oxygen (O). Silicon nitride oxide (SiNₓO_{y}) and aluminum nitride oxide (AlNₓO_{y}) are a silicon compound and an aluminum compound, respectively, that contain a smaller proportion (x>y) of oxygen than nitrogen. Further, each of the first insulating layer 110, the second insulating layer 120, the third insulating layer 170, and the fourth insulating layer 180 may have a single layer structure or a laminated structure.

Further, each of the first insulating layer 110, the second insulating layer 120, the third insulating layer 170, and the fourth insulating layer 180 may have a planarization function or a function of releasing oxygen by a heat treatment. For example, when the second insulating layer 120 has a function of releasing oxygen by the heat treatment, oxygen is released from the second insulating layer 120 by the heat treatment performed in the manufacturing process of the thin film transistor 10, and the released oxygen can be supplied to the oxide semiconductor layer 140.

The gate electrode 160, the source electrode 201, and the drain electrode 203 are conductive. For example, copper (Cu), aluminum (Al), titanium (Ti), chromium (Cr), cobalt (Co), nickel (Ni), molybdenum (Mo), hafnium (Hf), tantalum (Ta), tungsten (W), or bismuth (Bi), or alloys or compounds thereof can be used for each of the gate electrode 160, the source electrode 201, and the drain electrode 203. Each of the gate electrode 160, source electrode 201, and drain electrode 203 may have a single layer structure or a laminated structure.

The gate insulating layer 150 includes an oxide having insulating properties. Specifically, silicon oxide (SiOₓ), silicon oxynitride (SiOₓN_{y}), aluminum oxide (AlOₓ), aluminum oxynitride (AlOₓN_{y}), or the like is used for the gate insulating layer 150. The gate insulating layer 150 preferably has a composition close to the stoichiometric ratio. Further, the gate insulating layer 150 preferably has few defects. For example, an oxide in which few defects are observed when evaluated by electron spin resonance (ESR) may be used for the gate insulating layer 150.

The metal oxide layer 130 includes a metal oxide having insulating properties. Specifically, a metal oxide having a band gap greater than or equal to 4 eV is used for the metal oxide layer 130. Further, for example, a metal oxide containing one or more metal elements selected from aluminum (Al), magnesium (Mg), calcium (Ca), scandium (Sc), gallium (Ga), germanium (Ge), strontium (Sr), nickel (Ni), tantalum (Ta), yttrium (Y), zirconium (Zr), barium (Ba), hafnium (Hf), cobalt (Co), and lanthanoid elements is used for the metal oxide layer 130. In particular, it is preferable to use a metal oxide containing aluminum (e.g., aluminum oxide, etc.) for the metal oxide layer 130. The metal oxide containing aluminum has high barrier properties against gases such as oxygen or hydrogen.

Further, the metal oxide layer 130 can also function as a buffer layer for the oxide semiconductor layer 140. For example, when a heat treatment is performed on the oxide semiconductor layer 140 in contact with the metal oxide layer 130, the crystallinity of the oxide semiconductor layer 140 can be improved.

The film thickness of the metal oxide layer 130 is not particularly limited to a specific value. The film thickness of the metal oxide layer 130 may be less than or equal to 20 nm, less than or equal to 15 nm, or less than or equal 10 nm. For example, the film thickness of the metal oxide layer 130 is greater than or equal to 2 nm and less than or equal to 20 nm, preferably greater than or equal to 2 nm and less than or equal to 15 nm, and more preferably greater than or equal to 2 nm and less than or equal to 10 nm.

The Poly-OS film described in the First Embodiment can be used as the oxide semiconductor layer 140.

Although the configuration of the thin film transistor 10 is described above, the thin film transistor 10 described above is a so-called top-gate transistor. The thin film transistor 10 can be modified in various ways. For example, when the light shielding layer 105 has conductivity, the thin film transistor 10 may have a structure in which the light shielding layer 105 functions as a gate electrode, and the first insulating layer 110 and the second insulating layer 120 function as gate insulating layers. In this case, the thin film transistor 10 is a so-called dual-gate transistor. Further, when the light shielding layer 105 has conductivity, the light shielding layer 105 may be a floating electrode and may be connected to the source electrode 201. Furthermore, the thin film transistor 10 may be a so-called bottom-gate transistor in which the light shielding layer 105 functions as a main gate electrode.

### [2. Method for Manufacturing Thin Film Transistor 10]

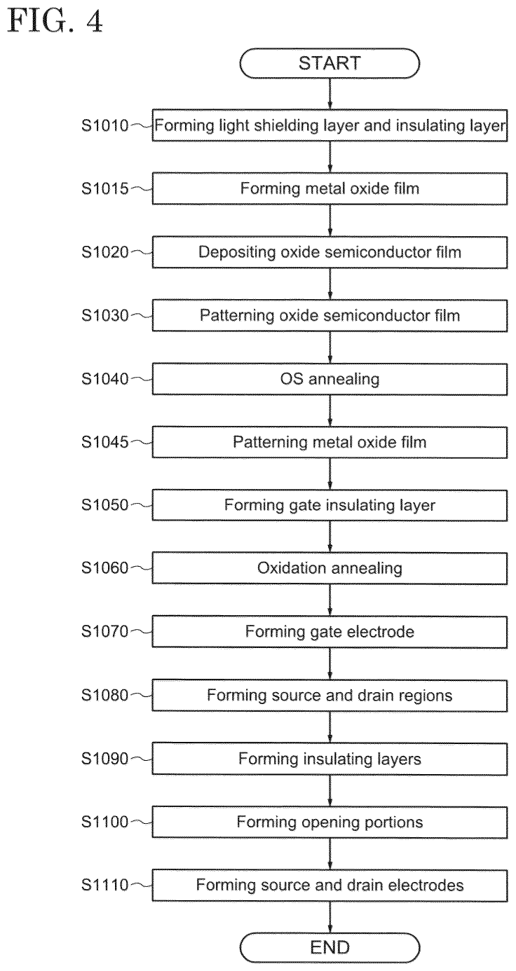

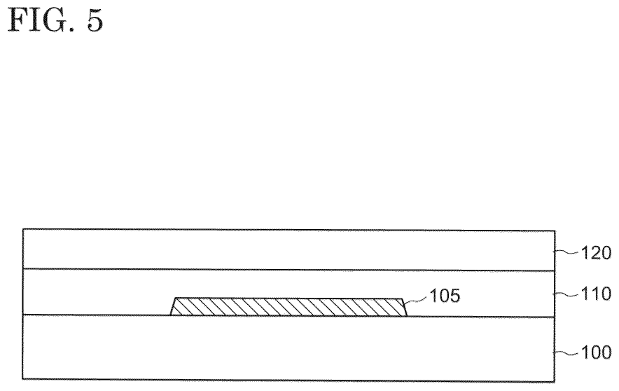

A method for manufacturing the thin film transistor 10 according to an embodiment of the present invention is described with reference to FIGS. 4 to 12. FIG. 4 is a flowchart showing the method for manufacturing the thin film transistor 10 according to an embodiment of the present invention. FIGS. 5 to 12 are schematic cross-sectional views showing the method of manufacturing the thin film transistor 10 according to an embodiment of the present invention.

As shown in FIG. 4, the method for manufacturing the thin film transistor 10 includes steps S1010 to S1110. In the following description, although the steps S1010 to S1110 are described in order, the order of the steps may be interchanged in the method for manufacturing the thin film transistor 10. Further, the method for manufacturing the thin film transistor 10 may include additional steps.

In step S1010, the light shielding layer 105 having a predetermined pattern is formed on the substrate 100. The patterning of the light shielding layer 105 is performed using a photolithography method. The first insulating layer 110 and the second insulating layer 120 are formed on the light shielding layer 105 (see FIG. 5). The first insulating layer 110 and the second insulating layer 120 are deposited using a CVD method. For example, a silicon nitride film and a silicon oxide film are deposited as the first insulating layer 110 and the second insulating layer 120, respectively. When the silicon nitride film is used as the first insulating layer 110, the first insulating layer 110 can block impurities that diffuse from the substrate 100 into the oxide semiconductor layer 140. When the silicon oxide film is used as the second insulating layer 120, the second insulating layer 120 can release oxygen by a heat treatment.

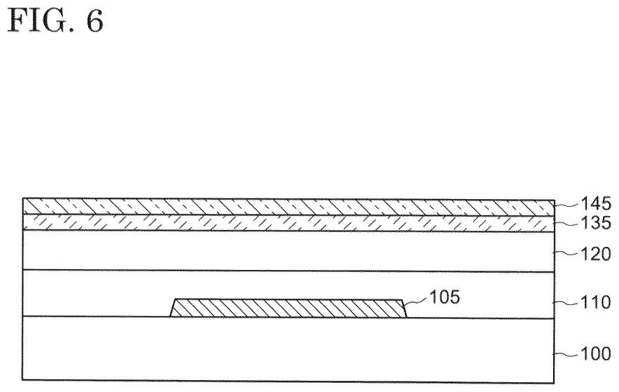

In step S1015, the metal oxide film 135 is formed on the second insulating layer 120 (see FIG. 6). The metal oxide film 135 is formed by a sputtering method. For example, the thickness of the metal oxide film 135 is greater than or equal to 2 nm and less than or equal to 20 nm, preferably greater than or equal to 2 nm and less than or equal to 15 nm, and more preferably greater than or equal to 2 nm and less than or equal to 10 nm.

In step S1020, an oxide semiconductor film 145 is deposited on the metal oxide film 135 (see FIG. 6). The oxide semiconductor film 145 is deposited by a sputtering method. For example, the thickness of the oxide semiconductor film 145 is greater than or equal to 10 nm and less than or equal to 100 nm, preferably greater than or equal to 15 nm and less than or equal to 70 nm, and more preferably greater than or equal to 15 nm and less than or equal to 40 nm.

The oxide semiconductor film 145 in step S1020 is amorphous. In the Poly-OS technology, the oxide semiconductor film 145 after the deposition and before the heat treatment is preferably amorphous so that the oxide semiconductor layer 140 has a uniform polycrystalline structure in the substrate plane. Therefore, the deposition conditions of the oxide semiconductor film 145 are preferably conditions under which the oxide semiconductor layer 140 immediately after the deposition is not crystallized as much as possible. When the oxide semiconductor film 145 is deposited by a sputtering method, the oxide semiconductor film 145 is deposited while controlling the temperature of the object to be deposited (the substrate 100 and the layers deposited on the substrate 100) to less than or equal to 100° C., preferably less than or equal to 80° C., and more preferably less than or equal to 50° C. The oxygen partial pressure is greater than or equal to 2% and less than or equal to 20%, preferably greater than or equal to 3% and less than or equal to 15%, and more preferably greater than or equal to 3% and less than 10%.

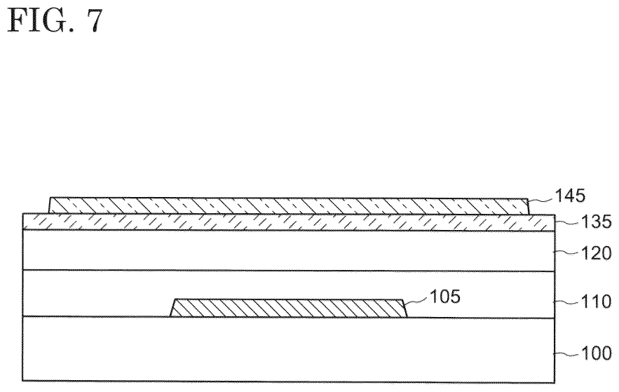

In step S1030, the oxide semiconductor film 145 is patterned (see FIG. 7). The patterning of the oxide semiconductor film 145 is performed using a photolithography method. Wet etching or dry etching may be used for the etching of the oxide semiconductor film 145. Wet etching can be performed using an acidic etchant. For example, oxalic acid, PAN, sulfuric acid, a hydrogen peroxide solution, hydrofluoric acid, or the like can be used for the etchant.

In step S1040, a heat treatment is performed on the oxide semiconductor film 145. Hereinafter, the heat treatment performed in step S1040 is referred to as “OS annealing”. In the OS annealing, the oxide semiconductor film 145 is held at a predetermined reaching temperature for a predetermined time. The predetermined reaching temperature is higher than or equal to 300° C. and lower than or equal to 500° C., and preferably higher than or equal to 350° C. and lower than or equal to 450° C. The predetermined time (holding time) at the reaching temperature is greater than or equal to 15 minutes and less than or equal to 120 minutes, and preferably greater than or equal to 30 minutes and less than or equal to 60 minutes. The oxide semiconductor film 145 is crystallized to form the oxide semiconductor layer 140 having a polycrystalline structure (that is, the oxide semiconductor including the Poly-OS) by the OS annealing.

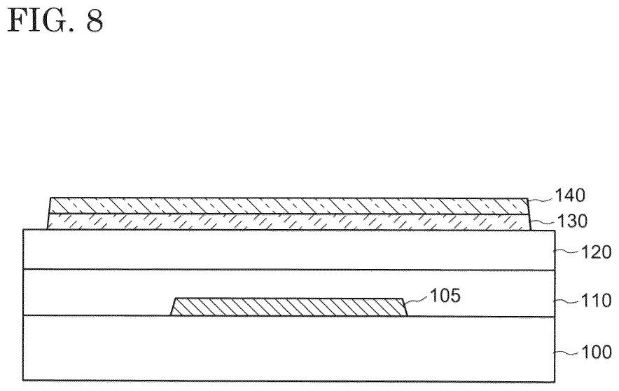

In step S1045, the metal oxide film 135 is patterned to form the metal oxide layer 130 (see FIG. 8). The metal oxide film 135 is etched using the oxide semiconductor layer 140 as a mask. When the patterned oxide semiconductor layer 140 is used as a mask, the photolithography process can be omitted. The metal oxide film 135 may be etched by wet etching or dry etching. For example, diluted hydrofluoric acid (DHF) is used in the wet etching.

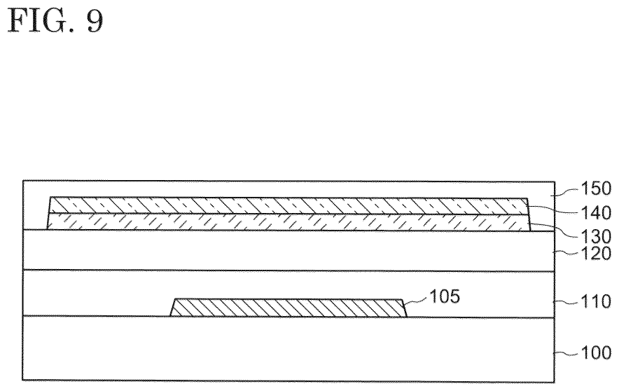

In step S1050, the gate insulating layer 150 is formed on the oxide semiconductor layer 140 (see FIG. 9). The gate insulating layer 150 is deposited using a CVD method. For example, silicon oxide is deposited for the gate insulating layer 150. In order to reduce defects in the gate insulating layer 150, the gate insulating layer 150 may be deposited at a deposition temperature higher than or equal to 350° C. The thickness of the gate insulating layer 150 is greater than or equal to 50 nm and less than or equal to 300 nm, preferably greater than or equal to 60 nm and less than or equal to 200 nm, and more preferably greater than or equal to 70 nm and less than or equal to 150 nm. After the gate insulating layer 150 is deposited, a treatment for introducing oxygen into a part of the gate insulating layer 150 may be performed.

In step S1060, a heat treatment is performed on the oxide semiconductor layer 140. Hereinafter, the heat treatment performed in step S1060 is referred to as “oxidation annealing”. When the gate insulating layer 150 is formed on the oxide semiconductor layer 140, many oxygen vacancies are generated on the top surface and side surfaces of the oxide semiconductor layer 140. When oxidation annealing is performed, oxygen is supplied from the second insulating layer 120 and the gate insulating layer 150 to the oxide semiconductor layer 140, and oxygen deficiencies are repaired.

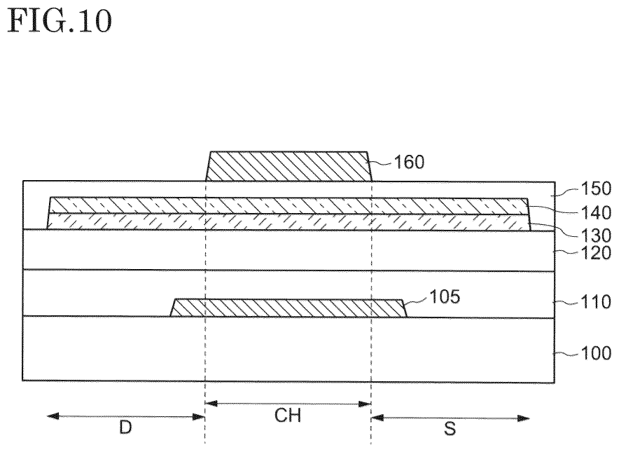

In step S1070, the gate electrode 160 having a predetermined pattern is formed on the gate insulating layer 150 (see FIG. 10). The gate electrode 160 is deposited by a sputtering method or an atomic layer deposition method, and patterning of the gate electrode 160 is performed using a photolithography method.

In step S1080, the source region S and the drain region D are formed in the oxide semiconductor layer 140 (see FIG. 10). The source region S and the drain region D are formed by ion implantation. Specifically, impurities are implanted into the oxide semiconductor layer 140 through the gate insulating layer 150 using the gate electrode 160 as a mask. For example, argon (Ar), phosphorus (P), boron (B), or the like is used as the implanted impurity. Oxygen deficiencies are generated by the ion implantation in the source region S and the drain region D that do not overlap the gate electrode 160, and hydrogen is trapped in the generated oxygen deficiencies. In this way, the resistance of the source region S and the drain region D is lowered. On the other hand, since no impurities are implanted in the channel region CH that overlaps the gate electrode 160, the resistance of the channel region CH is not lowered.

In addition, in the thin film transistor 10, since impurities are implanted into the oxide semiconductor layer 140 through the gate insulating layer 150, impurities such as argon (Ar), phosphorus (P), boron (B), or the like are included in the gate insulating layer 150.

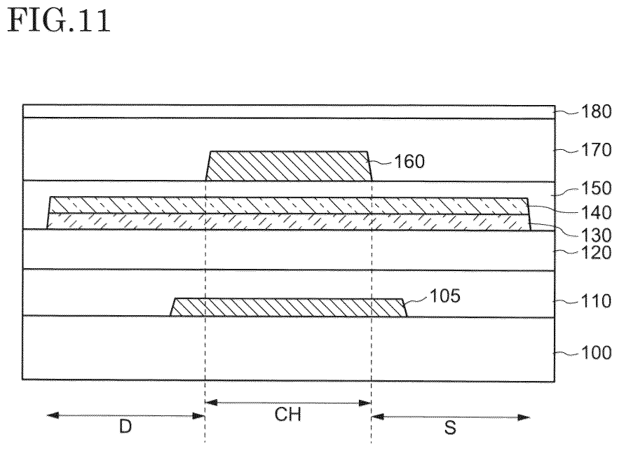

In step S1090, the third insulating layer 170 and the fourth insulating layer 180 are formed over the gate insulating layer 150 and the gate electrode 160 (see FIG. 11). The third insulating layer 170 and the fourth insulating layer 180 are deposited using a CVD method. For example, silicon oxide and silicon nitride are deposited for the third insulating layer 170 and the fourth insulating layer 180, respectively. The thickness of the third insulating layer 170 is greater than or equal to 50 nm and less than or equal to 500 nm. The thickness of the fourth insulating layer 180 is also greater than or equal to 50 nm and less than or equal to 500 nm.

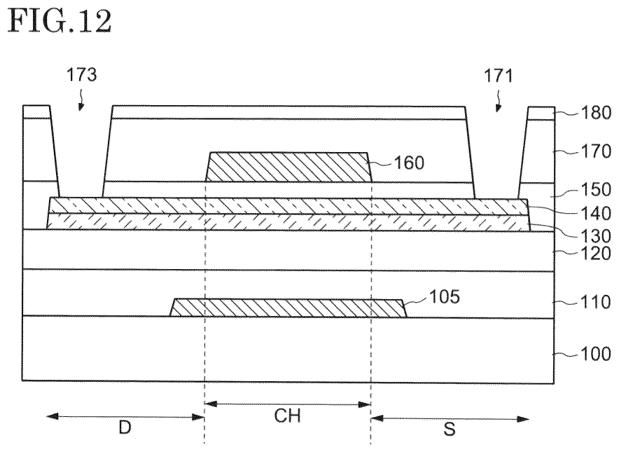

In step S1100, the opening portions 171 and 173 are formed in the gate insulating layer 150, the third insulating layer 170, and the fourth insulating layer 180 (see FIG. 12). The source region S and the drain region D of the oxide semiconductor layer 140 are exposed by the formation of the opening portions 171 and 173.

In step S1110, the source electrode 201 is formed on the fourth insulating layer 180 and inside the opening portion 171, and the drain electrode 203 is formed on the fourth insulating layer 180 and inside the opening portion 173. The source electrode 201 and the drain electrode 203 are formed as the same layer. Specifically, the source electrode 201 and the drain electrode 203 are formed by patterning one deposited conductive film. The thin film transistor 10 shown in FIG. 2 is manufactured through the above steps.

Although the method for manufacturing the thin film transistor 10 is described above, the method for manufacturing the thin film transistor 10 is not limited thereto.

In the thin film transistor 10 according to the present embodiment, the oxide semiconductor layer 140 includes the Poly-OS film having a novel crystal structure. Although the details are described later, the thin film transistor 10 including the Poly-OS film having such a novel crystal structure has improved electrical characteristics. For example, the field effect mobility of the thin film transistor 10 is improved.

### Third Embodiment

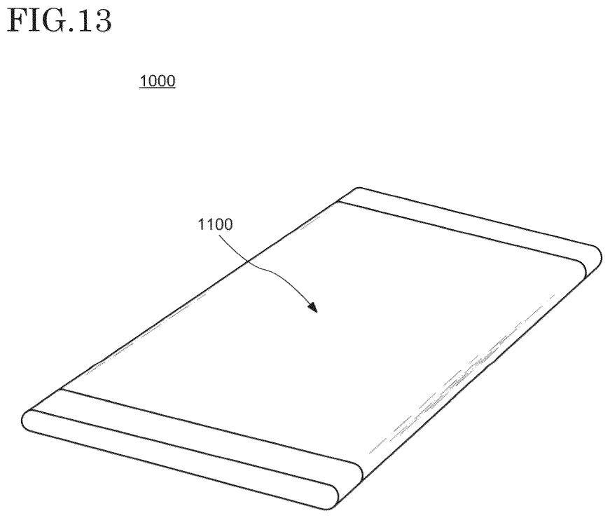

An electronic device according to an embodiment of the present embodiment is described with reference to FIG. 13.

FIG. 13 is a schematic diagram showing an electronic device 1000 according to an embodiment of the present embodiment. Specifically, FIG. 13 shows a smartphone, which is an example of the electronic device 1000. The electronic device 1000 includes a display device 1100 with curved sides. The display device 1100 includes a plurality of pixels for displaying an image. The plurality of pixels are controlled by a pixel circuit, a drive circuit, and the like. The pixel circuit and the drive circuit include the thin film transistor 10 described in the Second Embodiment. Since the thin film transistor 10 has high field effect mobility, the responsiveness of the pixel circuit and the drive circuit can be improved, and as a result, the performance of the electronic device 1000 can be improved.

In addition, the electronic device 1000 according to the present embodiment is not limited to a smartphone. For example, the electronic device 1000 also includes an electronic device having a display device, such as a watch, a tablet, a notebook computer, a car navigation system, or a television. The oxide semiconductor film described in the First Embodiment or the thin film transistor 10 described in the First Embodiment can be applied to any electronic device, regardless of whether or not the electronic device has a display device.

### EXAMPLES

Thin film samples and thin film transistors including an oxide semiconductor film were fabricated as samples. Hereinafter, the Poly-OS film is described in more detail based on the fabricated samples.

### [1. Fabrication of Samples]

The oxide semiconductor films in the thin film samples or thin film transistors were manufactured by a sputtering process and an OS annealing process. In the sputtering process, a sputtering target in which indium was 70% in terms of atomic ratio to all metal elements contained in the sintered body was used. In each sample, the chemical composition of the oxide semiconductor film after the OS annealing process was similar to that of the sputtering target. In the OS annealing process, the reached temperature was controlled to be between 350° C. and 450° C.

### 1-1. Example 1

### [1-1-1. Thin Film Sample]

A laminated film of a silicon oxide film (SiOₓ) and an aluminum oxide film (AlOₓ) was formed as a base film on a glass substrate. The silicon oxide film was deposited on the glass substrate by a plasma CVD method using monosilane (SiH₄) gas and dinitrogen monoxide (N₂O) gas. The aluminum oxide film was deposited on the silicon oxide film by a sputtering method using an aluminum (Al) target.

An oxide semiconductor film of 15 nm was deposited on a glass substrate on which the base film (AlOₓ/SiOₓ) was formed, using a sputtering process. The oxide semiconductor film was deposited under conditions in which the oxygen partial pressure was 3% (Example 1-1) or 5% (Example 1-2). Then, an OS annealing process was performed on the deposited oxide semiconductor film in an air atmosphere.

### [1-1-2. Thin Film Transistor]

A thin film transistor was fabricated by applying the conditions of Example 1-1 or Example 1-2 in the manufacturing method described in the Second Embodiment.

In addition, 16 samples (Examples 1-1-1 to 1-1-6) were fabricated under the conditions of Example 1-1, and 2 samples (Examples 1-2-1 and 1-2-2) were fabricated under the conditions of Example 1-2 for each of the thin film samples and the thin film transistors.

### 1-2. Example 2

### [1-2-1. Thin Film Sample]

An oxide semiconductor film of 20 nm was deposited on a glass substrate on which the base film (AlOₓ/SiOₓ) was formed, using a sputtering process. The oxide semiconductor film was formed under conditions in which the oxygen partial pressure was 3% (Example 2-1) or 5% (Example 2-2). Then, an OS annealing process was performed on the deposited oxide semiconductor film in an air atmosphere.

### [1-2-2. Thin Film Transistor]

A thin film transistor was fabricated by applying the conditions of Example 2-1 or Example 2-2 in the manufacturing method described in the Second Embodiment.

In addition, 2 samples (Examples 2-1-1 and 2-1-2) were fabricated under the conditions of Example 2-1, and 2 samples (Examples 2-2-1 and 2-2-2) were fabricated under the conditions of Example 2-2 for each of the thin film samples and the thin film transistors.

### 1-3. Example 3

### [1-3-1. Thin Film Sample]

An oxide semiconductor film of 25 nm was deposited on a glass substrate on which the base film (AlOₓ/SiOₓ) was formed, using a sputtering process. The oxide semiconductor film was formed under conditions in which the oxygen partial pressure was 3% (Example 3-1) or 4% (Example 3-2). Then, an OS annealing process was performed on the deposited oxide semiconductor film in an air atmosphere.

### [1-3-2. Thin Film Transistor]

A thin film transistor was fabricated by applying the conditions of Example 3-1 or Example 3-2 in the manufacturing method described in the Second Embodiment.

In addition, 2 samples (Examples 3-1-1 and 3-1-2) were fabricated under the conditions of Example 3-1, and 2 samples (Examples 3-2-1 and 3-2-2) were fabricated under the conditions of Example 3-2 for each of the thin film samples and the thin film transistors.

### 1-4. Example 4

### [1-4-1. Thin Film Sample]

An oxide semiconductor film of 30 nm was deposited on a glass substrate on which the base film (AlOₓ/SiOₓ) was formed, using a sputtering process. The oxide semiconductor film was formed under conditions in which the oxygen partial pressure was 3% (Example 4-1) or 4% (Example 4-2). Then, an OS annealing process was performed on the deposited oxide semiconductor film in an air atmosphere.

### [1-4-2. Thin Film Transistor]

A thin film transistor was fabricated by applying the conditions of Example 4-1 or Example 4-2 in the manufacturing method described in the Second Embodiment.

In addition, 2 samples (Examples 4-1-1 and 4-1-2) were fabricated under the conditions of Example 4-1, and 2 samples (Examples 4-2-1 and 4-2-2) were fabricated under the conditions of Example 4-2 for each of the thin film samples and the thin film transistors.

### 1-5. Comparative Example

### [1-5-1. Thin Film Sample]

An oxide semiconductor film of 30 nm was deposited on a glass substrate on which only a silicon oxide film (SiOₓ) was formed as a base film, using a sputtering process. The oxide semiconductor film was formed under conditions in which the oxygen partial pressure was 5%. Then, an OS annealing process was performed on the deposited oxide semiconductor film in an air atmosphere.

### [1-5-2. Thin Film Transistor]

A thin film transistor without a metal oxide layer was fabricated using the manufacturing method described in the Second Embodiment. That is, the oxide semiconductor layer in the thin film transistor of the Comparative Example was formed on and in contact with the second insulating layer (SiOₓ).

The conditions for the fabricated samples are shown in Table 1.

TABLE 1

| | | Thickness | Oxygen Partial |
|---|---|---|---|
| | | of Oxide | Pressure during Film |
| Sample | Base | Semiconductor | Formation of Oxide |
| Name | Film | Film | Semiconductor Film |
| Example 1-1 | AlOₓ/SiOₓ | 15 nm | 3% |
| Example 1-2 | AlOₓ/SiOₓ | 15 nm | 5% |
| Example 2-1 | AlOₓ/SiOₓ | 20 nm | 3% |
| Example 2-2 | AlOₓ/SiOₓ | 20 nm | 5% |
| Example 3-1 | AlOₓ/SiOₓ | 25 nm | 3% |
| Example 3-2 | AlOₓ/SiOₓ | 25 nm | 4% |
| Example 4-1 | AlOₓ/SiOₓ | 30 nm | 3% |
| Example 4-2 | AlOₓ/SiOₓ | 30 nm | 4% |
| Comparative | SiOₓ | 30 nm | 5% |
| Example | | | |

### [2. Crystal Structure Analysis by XRD Method]

The crystal structure of the fabricated film sample of the oxide semiconductor film was analyzed by an XRD method. The crystal structure analysis by the XRD method was performed using a SmartLab device (manufactured by Rigaku Corporation) under the conditions shown in Table 2.

TABLE 2

| X-ray Source | Cu-Kα | |
|---|---|---|
| Tube Voltage | 45 | kV |
| Tube Current | 200 | mA |
| Optical System | Parallel Beam Method | |
| Slit Configuration | Solar slit 5 degrees, | |
| | Entrance slit 1 mm, | |
| | Receiving slit 1 mm, | |
| | Incident length limiting slit 10 mm | |
| Scanning Range | 29 to 33 degrees, | |
| (2θ measurement: (out-of-plane)) | 50 to 54 degrees | |
| Measurement Width | 0.05 | degrees |
| Scanning Speed | 0.5 | deg/min |

In order to calculate the maximum intensity of each peak of the (222) plane and the (440) plane from the measurement results, five-point smoothing by the Savitzky-Golay method was performed on the measurement results using an analysis program (JADE 6), and then the crystal phase was identified using the crystal structure file of the bixbyite structure of 14388 of ICSD (Inorganic Crystal Structure Database: Chemical Information Association). After the identification of the crystalline phase, background noise was removed by linear approximation in each of the scanning ranges of 29 to 33 degrees and 50 to 54 degrees.

In the diffraction patterns of all the thin film samples, peaks of the (222) plane and the (440) plane of the bixbyite structure were observed. That is, all the thin film samples were Poly-OS films. When the ratio (D/t) of the crystallite diameter D to the film thickness t of the oxide semiconductor film was calculated, D/t was greater than or equal to 0.75 in all the thin film samples. Further, D/t was greater than or equal to 0.95 in the thin film samples of Examples 1-1-1 to 1-1-16.

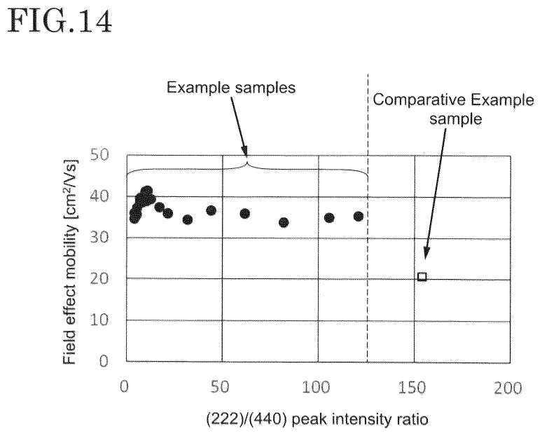

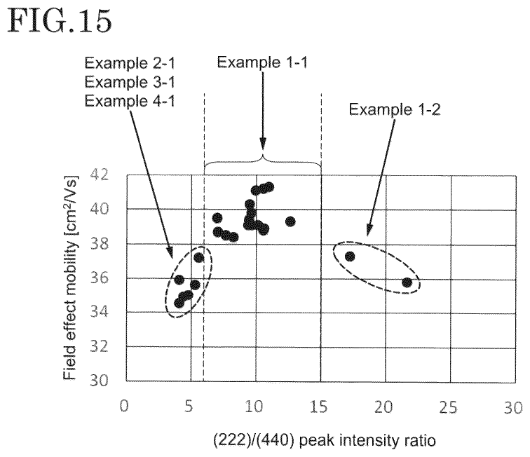

The (222)/(440) peak intensity ratio of the oxide semiconductor film was calculated from the diffraction pattern of the thin film sample, and the field effect mobility was calculated from the electrical characteristics of the thin film transistor. Table 3 shows the (222)/(440) peak intensity ratio and the field effect mobility of each sample. Further, FIGS. 14 and 15 show graphs in which the field effect mobility is plotted against the (222)/(440) peak intensity ratio. FIG. 15 is a graph in which the horizontal axis of the graph in FIG. 14 is expanded to a range of 0 to 30, and the vertical axis is expanded to a range of 30 to 42 cm²/Vs.

TABLE 3

| | | Field Effect | |
|---|---|---|---|
| | (222)/(440) Peak | Mobility | S/N |
| Sample Name | Intensity Ratio | [cm²/Vs] | Ratio |
| Example 1-1-1 | 10.97 | 41.3 | 34 |
| Example 1-1-2 | 10.57 | 41.2 | 33 |
| Example 1-1-3 | 9.95 | 41.1 | 30 |
| Example 1-1-4 | 9.49 | 40.3 | 19 |
| Example 1-1-5 | 9.63 | 39.8 | 25 |
| Example 1-1-6 | 7.00 | 39.5 | 25 |
| Example 1-1-7 | 9.46 | 39.4 | 29 |
| Example 1-1-8 | 12.64 | 39.3 | 27 |
| Example 1-1-9 | 10.14 | 39.1 | 31 |
| Example 1-1-10 | 9.38 | 39.1 | 29 |
| Example 1-1-11 | 9.65 | 39.1 | 32 |
| Example 1-1-12 | 10.60 | 38.9 | 27 |
| Example 1-1-13 | 10.57 | 38.8 | 25 |
| Example 1-1-14 | 7.04 | 38.7 | 21 |
| Example 1-1-15 | 7.68 | 38.5 | 15 |
| Example 1-1-16 | 8.25 | 38.4 | 19 |
| Example 1-2-1 | 17.24 | 37.3 | 44 |
| Example 1-2-2 | 21.63 | 35.8 | 41 |
| Example 2-1-1 | 5.29 | 35.6 | 33 |
| Example 2-1-2 | 5.57 | 37.2 | 26 |
| Example 2-2-1 | 44.14 | 36.5 | 74 |
| Example 2-2-2 | 105.64 | 34.9 | 133 |
| Example 3-1-1 | 4.08 | 35.9 | 42 |
| Example 3-1-2 | 4.39 | 34.9 | 36 |
| Example 3-2-1 | 63.02 | 35.8 | 152 |
| Example 3-2-2 | 31.80 | 34.3 | 93 |
| Example 4-1-1 | 4.77 | 35.0 | 69 |
| Example 4-1-2 | 4.08 | 34.5 | 41 |
| Example 4-2-1 | 82.00 | 33.7 | 244 |
| Example 4-2-2 | 120.96 | 35.2 | 207 |
| Comparative Example | 154.10 | 20.7 | 181 |

As shown in Table 3 and FIG. 14, when the (222)/(440) peak intensity ratio of the oxide semiconductor film was less than or equal to 125, the field effect mobility of the thin film transistor exceeded 30 cm²/Vs. Although all of the samples were Poly-OS films, it was found that the field effect mobility was improved by controlling the crystallinity of the Poly-OS film (more specifically, the (222)/(440) peak intensity ratio). In particular, the thin film transistors of Examples 1-1-1 to 1-1-16, which had the (222)/(440) peak intensity ratio less than or equal to 15, had the field effect mobility greater than or equal to 38 cm²/Vs.

The (222)/(440) peak intensity ratio of the Poly-OS film varies depending on the base layer. When the Poly-OS film is formed on the metal oxide film, the (222)/(440) peak intensity ratio of the Poly-OS film decreases. The (222)/(440) peak intensity ratio of the Poly-OS film can be controlled by the film thickness of the Poly-OS film and the oxygen partial pressure during film formation. When the film thickness of the Poly-OS film is small or the oxygen partial pressure during film formation is reduced, the (222)/(440) peak intensity ratio of the Poly-OS film decreases. In this manner, the electrical characteristics of the thin film transistor can be improved by controlling the (222)/(440) peak intensity ratio of the Poly-OS film.

Further, as shown in FIG. 15, the field effect mobility increases as the (222)/(440) peak intensity ratio decreases up to about 10. However, when the (222)/(440) peak intensity ratio further decreases beyond the boundary of about 10, the field effect mobility decreases. That is, the (222)/(440) peak intensity ratio of the Poly-OS film has a range in which the field effect mobility is particularly improved. Specifically, when the (222)/(440) peak intensity ratio of the Poly-OS film is greater than or equal to 6 and less than or equal to 15, the field effect mobility greater than or equal to 38 cm²/Vs can be obtained. When the (222)/(440) peak intensity ratio of the Poly-OS film is greater than or equal to 9 and less than or equal to 12, the field effect mobility greater than or equal to 40 cm²/Vs can be obtained. When the (222)/(440) peak intensity ratio of the Poly-OS film is controlled within the above range, the electrical characteristics of the thin film transistor can be further improved.

Each of the embodiments described above as an embodiment of the present invention can be appropriately combined and implemented as long as no contradiction is caused. Further, the addition, deletion, or design change of components, or the addition, deletion, or condition change of processes as appropriate by those skilled in the art based on each of the embodiments are included in the scope of the present invention as long as they are provided with the gist of the present invention.

It is understood that, even if the effect is different from those provided by each of the above-described embodiments, the effect obvious from the description in the specification or easily predicted by persons ordinarily skilled in the art is apparently derived from the present invention.

What is claimed is:

1. A laminated structure, comprising:
a metal oxide layer; and
an oxide semiconductor layer having crystallinity over and in contact with the metal oxide layer,
wherein a crystal structure of the oxide semiconductor layer is a bixbyite structure,
wherein at least a first peak of a (222) plane and a second peak of a (440) plane are observed in a diffraction pattern of the oxide semiconductor layer obtained by an out-of-plane XRD measurement using Cu—Kα radiation, and
wherein a ratio of an intensity of the first peak to an intensity of the second peak is greater than or equal to 6 and less than or equal to 15.

2. The laminated structure according to claim 1, wherein the ratio of the intensity of the first peak to the intensity of the second peak is greater than or equal to 9 and less than or equal to 15.

3. The laminated structure according to claim 1, wherein in the diffraction pattern, an S/N ratio of the intensity of the first peak to a noise width calculated from a diffraction angle (2θ) of 29 degrees to 30 degrees is greater than or equal to 15.

4. The laminated structure according to claim 3, wherein the noise width is calculated using a standard deviation in linear approximation.

5. The laminated structure according to claim 1,
wherein the oxide semiconductor layer comprises:
indium; and
at least one or more metal elements other than the indium,
wherein a ratio of the indium to the indium and the at least one or more metal elements is greater than or equal to 50%.

6. The laminated structure according to claim 1, wherein a film thickness of the oxide semiconductor layer is less than or equal to 20 nm.

7. The laminated structure according to claim 1, wherein the metal oxide layer comprises a metal oxide having a band gap greater than or equal to 4 eV.

8. The laminated structure according to claim 1, wherein the metal oxide film comprises one or more metal elements selected from the group consisting of aluminum, magnesium, calcium, scandium, gallium, germanium, strontium, nickel, tantalum, yttrium, zirconium, barium, hafnium, cobalt, and lanthanoid elements.

9. The laminated structure according to claim 1, wherein the metal oxide layer comprises aluminum oxide.

10. The laminated structure according to claim 1, wherein a film thickness of the metal oxide layer is less than or equal to 20 nm.

11. The laminated structure according to claim 1, wherein a ratio of a crystallite diameter calculated from the first peak to a film thickness of the semiconductor film is greater than or equal to 0.95.

12. A thin film transistor comprising:
the laminated structure according to claim 1;
a gate electrode provided so as to face the oxide semiconductor layer; and
a gate insulating layer between the oxide semiconductor layer and the gate electrode.

13. The thin film transistor according to claim 12, wherein a field effect mobility is greater than or equal to 40 cm²/Vs.

14. An electronic device comprising the thin film transistor according to claim 12.
